(19) United States
(12) Patent Application Publication
(10) Pub. No.: US 2009/0029504 A1
(43) Pub. Date: Jan. 29, 2009

(54) WAFER-LEVEL ACA FLIP CHIP PACKAGE USING DOUBLE-LAYERED ACA/NCA

(75) Inventors: Kyung-Wook PAIK, Daejeon (KR); Kyung-Woon JANG, Daejeon (KR); Il KIM, Daejeon (KR)

Correspondence Address: THE RAFFERTY PATENT LAW FIRM, 1952 Gallows Road, Suite 200, Vienna, VA, 22182-3823, US

(73) Assignee: KOREA ADVANCED INSTITUTE OF SCIENCE AND TECHNOLOGY, Daejeon (KR)

(21) Appl. No.: 12/177,993

(22) Filed: Jul. 23, 2008

(30) Foreign Application Priority Data
Jul. 23, 2007 (KR) 10-2007-0073637

(51) Int. Cl. H01L 21/58

(52) U.S. Cl. 438/108; 257/E21.505

(57) ABSTRACT

A method of manufacturing a wafer-level flip chip package is capable of being used to produce a flip chip package by directly coating a flip chip package using anisotropic conductive adhesives (ACA) and non conductive adhesives (NCA) in a solution state as a double layer on a wafer. The method can be used to manufacture a non-conductive mixed solution and a conductive mixed solution and directly coat them on a substrate, such that it is possible to: increase productivity; simplify a manufacturing process; suppress a shadow effect; easily perform thickness control that is difficult with the anisotropic conductive adhesive paste or the non-conductive adhesive paste; and obtain the non-conductive layer and the anisotropic conductive layer in an initial state of a B-stage with a level not losing latent of hardening through a simple drying process to volatilize an organic solvent. Above all, the non-conductive layer and the anisotropic conductive layer is sequentially stacked on the substrate formed with the non-solder bump, making it possible to make the selectivity of electrical conduction and the stability of a connection process excellent, shorten process time and costs, and dramatically reduce consumption of the conductive particles which account for a large portion of total production costs.

### CROSS-REFERENCE TO RELATED APPLICATION

The benefit of priority is claimed to Republic of Korea Patent Application No. 2007-0073637, filed with the Korean Intellectual Property Office on Jul. 23, 2007, which is hereby incorporated by reference.

### BACKGROUND

1. Introduction

The present discussion relates to a method of manufacturing a wafer-level flip chip package capable of being used to produce a flip chip package by directly coating a flip chip package using anisotropic conductive adhesives (hereinafter, referred to as ACA) and non-conductive adhesives (hereinafter, referred to as NCA) in a solution state as a double layer on a wafer.

2. Related Art

An electronic package technology, which is a very broad and various system manufacturing technology including all steps from a semiconductor device to a final product, is a very important technology in achieving miniaturization, lightweight, and high performance of devices to meet a rapid development speed of electronic products. The electronic package technology is a very important technology for determining performance, size, price, reliability, etc. of the final electronic products. In particular, ultra-miniaturization package parts for recent electronic products that are pursuing high electrical performance, ultra-miniaturization/high density, low power, multifunction, ultra-high speed signal processing, permanent reliability, etc., are essential parts for computer products, information communication products, mobile communication products, premium consumer products, etc. Flip chip technology, which is one of the technologies for mounting a dual chip on a substrate, is used in smart cards, display packaging such as for LCDs, PDPs, etc., computers, cellular phones, communication systems, and the like.

Flip chip technology has been largely divided into two, that is, a solder flip chip using solder and a non-solder flip chip not using solder. Since the solder flip chip has a complicated connection process such as solder flux coating, chip/substrate alignment, solder bump reflow, flux removal, underfill filling, and hardening, etc., it has a problem of increasing manufacturing costs. Therefore, in order to reduce the complicated processes, the non-solder flip chip technology has been recently spotlighted.

A representative technology of the non-solder flip chip is the flip chip technology using anisotropic conductive adhesives (ACA). The flip chip technology using an existing ACA has a process that applies or temporarily adheres an ACA material on the substrate, aligns the chip and substrate, and finally applies heat and pressure to complete the flip chip package. However, such a process requires a long process time for performing the formation of the film or the application or temporary adhesion of the ACA material on every substrate.

For these reasons, a wafer-level anisotropic conductive film (ACF) package technology, which applies and processes polymer materials having functions of the flux and underfill in a wafer state has recently been receiving much attention. Also, a development of flip chip connection technology using conductive adhesives with advantages such as lowering of manufacturing costs compared to a general solder flip chip, achieving an ultra-fine electrode pitch and a lead free, and performing an eco-friendly fluxless process at low-temperature has been progressed.

The adhesives used for the electronic package are sorted into the Isotropic Conductive Adhesives (hereinafter, referred to as ICA), Anisotropic Conductive Adhesives (hereinafter, ACA) and Non-Conductive Adhesives (hereinafter, NCA). Also, the ACA is sorted into the Anisotropic Conductive Film (hereinafter, ACF) and Anisotropic Conductive Paste (hereinafter, ACP) according to its form. Also, the NCA is sorted into the Non-Conductive Film (hereinafter, NCF) and Non-Conductive Paste (hereinafter, NCP) according to its form.

The adhesives in a film form and the adhesives in a paste form have a large difference therebetween according to their form and composition. First, the ACF includes an organic solution (MEK, toluene, or the like) improving coatability among compositions so that it can be coated in the film form. The ACF is commercialized after it is coated in a film form and the organic solution is dried. Unlike the film, the ACP performs the flip chip process by being directly applied on the substrate using a method such as a dispensing, etc., as such, it does not include the organic solution in order to prevent the formation of bubbles in the inside thereof. It is commercialized by being put in a syringe in paste form. In other words, the kind or amount of the organic solution included in the ACF or NCF solutions is controlled so that Theological characteristics are controlled, making it possible to coat the ACF or NCF in film form. The currently commercialized ACP and NCP products cannot be coated in film form for dispensing.

A common point in view of the composition of two materials, that is, the film and the paste, is that they may include thermosetting or thermoplastic insulating resin and hardener and may include conductive particles such as nickel (Ni), gold (Au)/polymer, silver (Ag), or the like according to the field of application.

As one example related to the present discussion, U.S. Pat. No. 5,323,051 (“Semiconductor wafer level package,” issued Jun. 21, 1994, incorporated herein by reference) that adheres another cap wafer using glass adhesives in a wafer state and then cuts the wafer into each chip, is very different from the present approach that makes the double layer by coating the NCA and ACA and uses it as the package connection.

As another example, U.S. Pat. No. 5,918,113 (“Process for producing a semiconductor device using anisotropic conductive adhesive,” issued Jun. 29, 1999, incorporated herein by reference) that is a method adhering the ACA on the substrate and then contacting the semiconductor chip to the substrate and applying heat and pressure to form an electrical connection therebetween is very different from the present approach that previously coats the NCA and ACA on the chip formed with the non-solder bump in the wafer state using the NCA and ACA solutions and forms the double layer of the NCA and ACA.

S. H. Shi et al. provides a method that simplifies a process of putting the underfill material between the chip and the substrate after the existing solder reflow connection by coating the underfill material including the solder flux function on the wafer formed with the solder bump and dicing each chip followed by aligning them on the substrate using an existing SMT assembly apparatus. Also, already published Korean Registered Patent No. 10-0361640 (“Wafer type flip chip package manufacturing method using coated anisotropic conductive adhesives,” registered Nov. 6, 2002, incorporated herein by reference) provides a process method that transfers ACF on to the wafer using a lamination process method of applying heat and pressure after coating the ACF on a release paper film and a process method that applies ACF on the wafer by a spray method, a doctor blade method, or a meniscus method. Therefore, when the film form is used, the lamination process of positioning the film on the wafer then applying heat and pressure thereto and the process of removing the release paper are needed, such that, when the ACA or the NCA in the film form is adhered on an uneven wafer surface, a shadow effect may easily occur, and when the paste form is used, the coating thickness is difficult to control. Also, since a single ACA layer is used, unwanted electrical conduction can be caused during the laminating process of applying heat and pressure.

However, unlike the process method of coating the ACF on the release paper and then applying it on the wafer using the lamination method, the present discussion forms the double layer film having a structure wherein the non-conductive layer and the anisotropic conductive layer are stacked by applying and drying the ACF and NCF solutions in a pre-coating state on the wafer, making it possible to provide a simple and inexpensive connection process method with excellent selectivity of electrical conduction.

### SUMMARY

It is an object of the present discussion to provide a wafer type flip chip package manufacturing method using anisotropic conductive adhesives (hereinafter, referred to as ACA) solution and non-conductive adhesives (hereinafter, referred to NCA) solution capable of effectively suppressing a shadow effect that may easily occur on an uneven wafer surface, improving selectivity of electrical conduction and stability of a connection process using ACA and NCA solutions that allows easy control of a coating thickness, simplifies manufacturing processes, shortens processing time and costs, and dramatically reduces consumption of conductive particles which account for a large portion of total production costs.

A flip chip manufacturing method of the present may include forming a non-conductive layer by applying and drying non-conductive mixed solution including insulating polymer resin, hardener, and organic solvent on a wafer formed with a non-solder bump; forming an anisotropic conductive layer by applying and drying conductive mixed solution including insulating polymer resin, hardener, organic solvent, and conductive particles on the non-conductive layer; manufacturing individual semiconductor chips by cutting the wafer formed with the non-conductive layer and the anisotropic conductive layer; and connecting flip chips by aligning the semiconductor chips with electrodes on the substrate.

At the step of forming the non-conductive layer, the thickness of the non-conductive layer may be equal to or thicker than that of the non-solder bump formed on the wafer so that the wafer is flattened by the non-conductive layer, the thickness of the non-conductive layer preferably being in the range of from 10 μm to 100 μm. The thickness of the anisotropic conductive layer is equal to or thicker than the sum of a thickness of the electrode on the substrate and a diameter of particles with a maximum size of the conductive particles. Preferably, the thickness of the anisotropic conductive layer is in the range of from 10 μm to 100 μm.

The insulating polymer resin of the non-conductive mixed solution at the step of forming the non-conductive layer and the insulating polymer resin of the conductive mixed solution at the step of forming the anisotropic conductive layer may include acrylic resin, phenoxy resin, rubber, epoxy resin, polyimide resin, or a mixture thereof, the organic solvent of the non-conductive mixed solution at the step of forming the non-conductive layer or the organic solvent of the conductive mixed solution at the step of forming the anisotropic conductive layer may include toluene, methyl ethyl ketone, acetone, dimethyl formamide, cyclohexane, or a mixture thereof, and the conductive particles of the conductive mixed solution at the step of forming the anisotropic conductive layer may include gold, silver, nickel, polymer coated with metal, conductive polymer, metal particles coated with insulating polymer, or a mixture thereof.

Preferably, the non-conductive mixed solution at the step of forming the non-conductive layer includes a mixture of 100 to 400 parts by weight of hardener and 25 to 300 parts by weight of organic solvent for every 100 parts by weight of insulating polymer resin and preferably, the conductive mixed solution at the step of forming the anisotropic conductive layer includes a mixture of 100 to 400 parts by weight of hardener, 50 to 200 parts by weight of organic solvent, and 10 to 150 parts by weight of conductive particles for every 100 parts by weight of insulating polymer resin.

Drying at the step of forming the non-conductive layer or the step of forming the anisotropic conductive layer is performed at 70 to 80° C. to volatilize the organic solvent and to make the non-conductive layer and the anisotropic conductive layer into an initial state of B-stage polymer, and the non-conductive layer at the step of forming the non-conductive layer or the anisotropic conductive layer at the step of forming the anisotropic conductive layer hardens within the range of from one second to one minute at 100 to 300° C.

Preferably, the application at the step of forming the non-conductive layer or the step of forming the anisotropic conductive layer is performed using a spray, a doctor blade, a meniscus, spin coating, screen printing, stencil printing, or comma roll coating.

### BRIEF DESCRIPTION OF THE DRAWINGS

These and other objects, features, and advantages of preferred embodiments of the present invention will be more fully described in the following detailed description, taken in conjunction with the accompanying drawings. In the drawings:

FIG. 1 is a view showing one example of a manufacturing method of the present invention, in which FIG. 1(a) shows a wafer, FIG. 1(b) is a cross-sectional view taken along line A-B of FIG. 1(a) and shows a step of forming a non-conductive layer, FIG. 1(c) is a cross-sectional view taken along line A-B of FIG. 1(a) and shows a step of forming an anisotropic conductive layer, FIG. 1(d) shows individually diced chips, FIG. 1(e) shows a connection of flip chips, and FIG. 1(f) shows a connected flip chip assembly.

### DETAILED DESCRIPTION

Example embodiments will now be described. A flip chip manufacturing method of the present discussion may include the steps of: (a) forming a non-conductive layer by applying and drying non-conductive mixed solution including insulating polymer resin, hardener, and organic solvent on a wafer formed with a non-solder bump; (b) forming an anisotropic conductive layer by applying and drying conductive mixed solution including insulating polymer resin, hardener, organic solvent, and conductive particles on the non-conductive layer; (c) manufacturing individual semiconductor chips by cutting the wafer formed with the non-conductive layer and the anisotropic conductive layer; and (d) connecting flip chips by aligning the semiconductor chips with electrodes on the substrate.

As described above, a material having composition of a non-conductive film NCF manufactured in a solution state (non-conductive mixed solution) and a material having composition of an anisotropic conductive film ACF manufactured (conductive mixed solution) in a solution state are directly coated on a wafer, making it possible to effectively suppress a shadow effect that may easily occur on an uneven wafer surface and to control a coating thickness that is difficult to achieve using anisotropic conductive adhesive paste or non-conductive adhesive paste.

The non-conductive layer performs a role of flattening the wafer with the uneven surface caused due to a formation of a non-solder bump and of dramatically reducing an amount of conductive particles required for an electrical connection of semiconductor chips and electrodes on a substrate.

In particular, when a conductive layer is formed on the uneven wafer by the bump, a flow of resin is changed by steps of the bumps so that many conductive particles do not remain at an upper region of the bump but may instead be compacted between the bumps. This phenomenon is a serious problem when a thickness of the film to be formed is approaching a height of the bump. In the case of an actual display driver IC, since the thickness of the film and the height of the bumps are similar and an interval between the bumps is narrow, this phenomenon causes problems such as electrical shorts. When evenness is achieved by the non-conductive layer of the present discussion and the conductive layer is formed on the flattened surface, the problem is removed, making it possible to prevent electrical shorts. Also, it can suppress the phenomenon that the conductive particles are compacted at one place due to the flow of resin.

Also, there can be obtained an anisotropic conductive layer and a non-conductive layer in a B-stage initial state with a level, which does not lose latent of hardening, through a simple process of volatilizing an organic solvent at the step (a) and the step (b).

At this time, since the difference of the materials of the non-conductive layer and the anisotropic conductive layer depends on only an absence or not of the conductive particles, the flip chips are connected using application (laminating process) of heat and pressure and ultrasonic vibration so that after the step (d) where hardening is completed, an interface of a double layer, configured of the non-conductive layer and the anisotropic conductive layer has the same intensity and junction characteristics as a single layer.

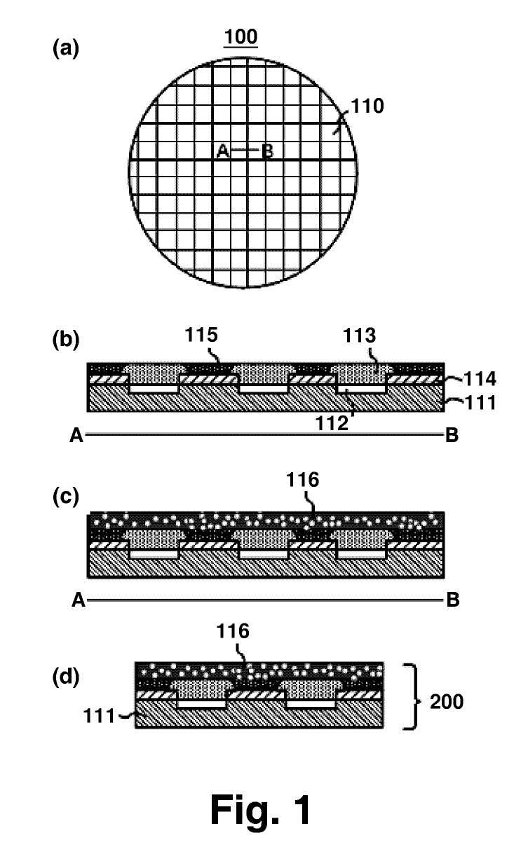

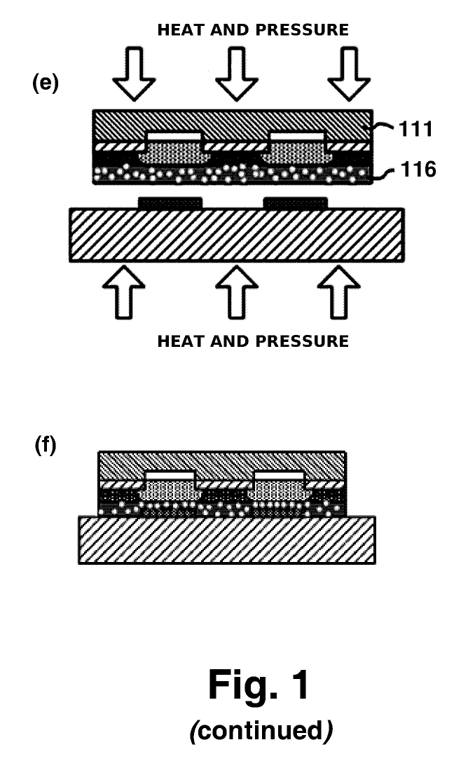

Hereinafter, a manufacturing method of the present discussion will be described more clearly with reference to FIG. 1. However, FIG. 1 is shown, by way of example, for explaining the present discussion and the present discussion is not limited thereto.

As shown in FIGS. 1(a) to 1(c), the wafer 100 to which a non-conductive mixed solution and a conductive mixed solution are applied is a wafer manufactured through a general semiconductor process. Generally, many chips 110 are formed on one wafer and each chip is provided with input/output pads (I/O pad, 112) for connecting electrical signals with an external circuit.

At this time, a kind of the chips is not particularly limited. For example, it may be a display driving circuit IC, an image sensor IC, a memory IC, a non-memory IC, an ultra high frequency or RF IC, a semiconductor IC using silicon as a main component, or a compound semiconductor IC.

The upper of the I/O pad is provided with a non-solder bump 113. The non-solder bump, which is a metal stud bump or a metal plating bump formed using a bonding wire bonder or a plating method, may be a gold stud bump, a copper stud bump, a gold plated bump, a copper plated bump, an electroless nickel/gold bump, or electroless nickel/copper/gold bump. The upper of the wafer on which the non-solder bump is not formed is generally passivated with an insulating material 114.

As shown in FIG. 1(b), the non-conductive mixed solution is applied on a surface on which the non-solder bump 113 for the wafer is formed by means of a spray, a doctor blade, a meniscus, spin coating, screen printing, stencil printing, or comma roll coating. The wafer on which the non-conductive mixed solution is applied is dried for 1 to 4 minutes at 70 to 80° C. to volatilize an organic solvent, wherein the non-conductive layer 115 applied through the drying becomes from an A-stage permitting easy flow to an initial state of a B-stage with physical properties capable of maintaining and modifying its shape at normal temperature during processing and with fluidity during heating. The initial state of the B-stage means a hardening initial state, having possibility that generates a hardening reaction only at a particular temperature or more among the states of the B-stage, that represents a point in time from the beginning of the hardening to the end of the hardening.

At this time, the thickness of the non-conductive layer 115 is preferably equal to or thicker than the thickness of the non-solder bumps formed on the wafer. As can be appreciated from FIG. 1(b), a prominence and depression caused due to the non-solder bump 113 is removed by the non-conductive layer 115 to make the wafer flat. Preferably, the thickness of the non-conductive layer 115 is 10 to 100 μm. This thickness is a sum of the general thickness of the non-solder bump 113 and, a thickness capable of obtaining physical adhesion required for the connection of the flip chips and minimizing the shadow effect.

After the non-conductive layer 115 is formed, the conductive mixed solution is applied on the upper of the non-conductive layer 115 by a spray, a doctor blade, a meniscus, spin coating, screen printing, stencil printing, or comma roll coating, as shown in FIG. 1(c). After the conductive mixed solution is applied, it is dried for 1 to 4 minutes at 70 to 80° C. to volatilize the organic solvent, wherein the anisotropic conductive layer 116 applied through the drying becomes from an A-stage permitting easy flow to an initial state of a B-stage with physical properties capable of maintaining and modifying its shape at normal temperature during processing and with fluidity during heating. At this time, as can be seen in FIG. 1(c), white circles inside an anisotropic conductive layer 116 represent the conductive particles of the conductive mixed solution.

The thickness of the anisotropic conductive layer 116 is equal to or thicker than the sum of a thickness of the electrode on the substrate and a diameter of particles with a maximum size of the conductive particles, that is, the thickness of the anisotropic conductive layer is a minimum thickness that can smoothly connect the electrodes on the substrate and the semiconductor chips. The thickness of the anisotropic conductive layer is preferably 10 to 100 μm.

As can be appreciated from FIG. 1(c): the non-conductive layer 115 and the anisotropic conductive layer 116 are stacked to prevent unwanted electrical conduction between the electrodes on the substrate, between the electrodes on the substrate and the semiconductor chips, and between the semiconductor chips; a space between the non-solder bump 113 and the electrode 310 on the substrate is filled by the non-conductive layer 115 to perform the adhesion and fixing; and the semiconductor chip and the electrode on the substrate are effectively and electrically connected by the anisotropic conductive layer 116. Also, the amount of the conductive particles required for the electrical connection of the semiconductor chip and the electrode on the substrate by the use of the non-conductive layer 115 is dramatically reduced.

The wafer on which the non-conductive layer 115 and the anisotropic conductive layer 116 are formed is mounted on the wafer dicing machine to dice it into individual chips 200 that are shown in FIG. 1(d), based on a scribe line of the wafer. Since the ACF or NCF in the state of the B-stage is adhered to the individually diced chips 200, each one can be used as one flip chip package. The individual chips 200 align with the electrodes 310 on the substrate 300 and the non-conductive layer 115 and the anisotropic conductive layer 116 are then hardened through the general laminating process that applies heat and pressure by the use of the flip chip bonder, making it possible to obtain a flip chip assembly in which the individual chips and the substrate are physically and electrically connected. At this time, the non-conductive layer or the anisotropic conductive layer are hardened within 1 second to 1 minute at 100 to 300° C.

As described above, a core idea of the present example is to control the Theological characteristics using an organic solvent that can allow the application of the ACF and NCF solutions (non-conductive mixed solution and conductive mixed solution) in the film form, to form a double layer of the non-conductive layer and the anisotropic conductor layer on the wafer on which the non-solder bump is formed, to make the wafer flat by filling the vacant space between the non-solder bumps by use of the non-conductive layer, and to obtain the individual chips by dicing the wafer on which the double layer is formed and to use the individual chips as the flip chip package.

The non-conductive mixed solution or the conductive mixed solution may be manufactured by mixing the materials forming the generally used ACF or NCF with the organic solvent. However, the non-conductive mixed solution at the step (a) is preferably a mixture of 100 to 400 parts by weight of hardener and 25 to 300 parts by weight of organic solvent for every 100 parts by weight of insulating polymer resin and the conductive mixed solution at the step (b) is preferably a mixture of 100 to 400 parts by weight of hardener, 50 to 200 parts by weight of organic solvent, and 10 to 150 parts by weight of conductive particle for every 100 parts by weight of insulating polymer resin.

The insulating polymer resin of the non-conductive mixed solution at the step (a) and the insulating polymer resin of the conductive mixed solution at the step (b) are acrylic resin, phenoxy resin, rubber, epoxy resin, polyimide resin, or a mixture thereof, the organic solvent of the non-conductive mixed solution at the step (a) or the organic solvent of the conductive mixed solution at the step (b) are toluene, methyl ethyl ketone, acetone, dimethyl formamide, cyclohexane, or a mixture thereof, the hardener of the non-conductive mixed solution at the step (a) or the hardener of the conductive mixed solution at the step (b) is an imidazole group or amine group or a mixture thereof, and the conductive particles of the conductive mixed solution at the step (b) are gold, silver, nickel, polymer coated with metal, conductive polymer, metal particles coated with insulating polymer, or a mixture thereof.

The weight ratio of the organic solvent is an optimized weight ratio to be able to control the thickness in the film form by coating and drying the non-conductive mixed solution or the conductive mixed solution including the composition similar to the materials forming the ACF or NCF on the surface of the generally manufactured wafer, however, the weight ratio of the organic solvent determining the Theological characteristic is preferably controlled by the unevenness of the surface of the wafer such as the thickness of the non-solder bump or the number of the non-solder bumps.

### FIRST EXAMPLE

Manufacturing Thermoplastic Epoxy Resin Solution

Thermoplastic epoxy resin solution was manufactured by mixing 40 g of phenoxy based epoxy (KUKDO Chemical Co., Ltd. YP 50), 20 g of MEK, and 30 g of toluene and milling for three days at room temperature.

Manufacturing Thermosetting Epoxy Resin Solution

Thermosetting epoxy resin solution was manufactured by mixing 40 g of bisphenol A type epoxy (KUKDO Chemical Co., Ltd. YD020L), 20 g of MEK, and 20 g of toluene and milling for three days at room temperature.

Manufacturing Non-Conductive Mixed Solution

Non-conductive mixed solution was manufactured by mixing 25 g of the manufactured thermoplastic epoxy resin solution, 15 g of the manufactured thermosetting epoxy resin solution, and 60 g of benzimidazole based latent hardener (Asahi Kasei chemical, HX3941HP) and stirring for five minutes at room temperature.

Manufacturing Conductive Mixed Solution

The non-conductive mixed solution was manufactured by mixing 25 g of the manufactured thermoplastic epoxy resin solution, 15 g of the manufactured thermosetting epoxy resin solution, 60 g of benzimidazole based latent hardener (Asahi Kasei chemical, HX3941HP), and 10 g of conductive particles, (Nippon Chemical, BRIGHT 24GNR3.8-HBM) comprising polymer beads coated with nickel, and stirring for fifteen minutes at room temperature.

Manufacturing Non-Conductive Layer on Upper of Wafer Formed with Non-Solder Bump

The non-conductive layer with a thickness of 20 μm is manufactured by coating the manufactured non-conductive mixed solution on a wafer formed with the non-solder bump at intervals of 40 μm using an automatic coater (CKAF-1006D, CK Co.) at room temperature and drying it for 90 seconds at 80° C. Manufacturing anisotropic conductive layer (complete double layer)

A conductive layer with a thickness of 30 μm is manufactured by coating the manufactured non-conductive mixed solution on the wafer formed with the non-conductive layer at a gap of 50 μm using an automatic coater (CKAF-1006D, CK Co.) at room temperature and drying it for 2 minutes at 80° C.

Manufacturing Individual Chips

Individual chips are manufactured by fixing the wafer tape formed with the double layer and dicing it using a dicing device (DAD3350, DISCO).

Connection of Flip Chips

A FR4 plate is formed with a Cu electrode and is aligned with the individual chips on the substrate subjected to an ENIG finished processing by a flip chip bonder (Fineplacer-lambda, Finetech) and then, a flip chip assembly is obtained by applying 40N pressure for 30 seconds at the substrate temperature of 80° C. and the individual chip temperature of 190° C. by the same device.

With the present example, since the materials with the composition of the anisotropic conductive film (ACF) and the non-conductive film (NCF) are directly coated on the wafer in the solution state, a process of laminating the anisotropic conductive film or the non-conductive film on the wafer and removing the release paper is not needed, such that: it possible to increase productivity and simplify manufacturing processes; the coating is performed in the solution state and not in the film state so that the shadow effect that may easily occur on the surface of the uneven surface can be suppressed; the thickness control that is difficult to achieve with the anisotropic conductive adhesive paste or the non-conductive adhesive paste can be easily performed; and the non-conductive layer and the anisotropic conductive layer in the initial state of the B-stage with the level not losing the latent of hardening can be obtained through a simple drying process that volatilizes the organic solvent. Above all, the non-conductive layer and the anisotropic conductive layer are sequentially stacked on the substrate formed with the non-solder bump, making it possible to make the selectivity of electrical conduction and the stability of a connection process excellent, shorten process time and costs, and dramatically reduce consumption of the conductive particles which account for a large portion of total production costs.

Although the present invention has been described in detail with reference to illustrative example embodiments set forth above, it will be understood by those skilled in the art that various modifications and equivalents can be made without departing from the spirit and scope of the present invention, as set forth in the appended claims.

What is claimed is:

1. A flip chip manufacturing method comprising the steps of:
(a) forming a non-conductive layer by applying and drying non-conductive mixed solution including insulating polymer resin, hardener, and organic solvent on a wafer formed with a non-solder bump;
(b) forming an anisotropic conductive layer by applying and drying conductive mixed solution including insulating polymer resin, hardener, organic solvent, and conductive particles on the non-conductive layer;
(c) manufacturing individual semiconductor chips by cutting the wafer formed with the non-conductive layer and the anisotropic conductive layer; and
(d) connecting flip chips by aligning the semiconductor chips with electrodes on the substrate.

2. The method according to claim 1, wherein at the step (a), the thickness of the non-conductive layer is equal to or thicker than that of the non-solder bump formed on the wafer so that the wafer is flattened by the non-conductive layer.

3. The method according to claim 2, wherein the thickness of the non-conductive layer is in a range of from 10 μm to 100 μm.

4. The method according to claim 1, wherein the thickness of the anisotropic conductive layer is equal to or thicker than the sum of a thickness of the electrode on the substrate and a diameter of particles with a maximum size of the conductive particles.

5. The method according to claim 1, wherein the thickness of the anisotropic conductive layer is in a range of from 10 μm to 100 μm.

6. The method according to claim 1, wherein the insulating polymer resin at the step (a) or the step (b) is at least one selected from a group consisting of acrylic resin, phenoxy resin, rubber, epoxy resin, and polyimide resin.

7. The method according to claim 1, wherein the organic solvent at the step (a) or the step (b) is at least one selected from a group consisting of toluene, methyl ethyl ketone, acetone, dimethyl formamide, and cyclohexane.

8. The method according to claim 1, wherein the conductive particle at the step (b) is at least one selected from a group consisting of gold, silver, nickel, polymer coated with metal, conductive polymer, and metal particles coated with insulating polymer.

9. The method according to claim 1, wherein the non-conductive mixed solution at the step (a) is a mixture of 100 to 400 parts by weight of hardener and 25 to 300 parts by weight of organic solvent for every 100 parts by weight of insulating polymer resin.

10. The method according to claim 1, wherein the conductive mixed solution at the step (b) is a mixture of 100 to 400 parts by weight of hardener, 50 to 200 parts by weight of organic solvent, and 10 to 150 parts by weight of conductive particles for every 100 parts by weight of insulating polymer resin.

11. The method according to claim 1, wherein drying at the step (a) or the step (b) is performed at 70° C. to 80° C. to volatilize the organic solvent and to make the non-conductive layer and the anisotropic conductive layer into an initial state of B-stage polymer.

12. The method according to claim 1, wherein the non-conductive layer at the step (a) or the anisotropic conductive layer at the step (b) is hardened for one second to one minute at a temperature of 100° C. to 300° C.

13. The method according to claim 1, wherein the application method at the step (a) or the step (b) is at least one selected from a group consisting of a spray, a doctor blade, a meniscus, spin coating, screen printing, stencil printing, and comma roll coating.
